(19) United States
(12) Patent Application Publication
(10) Pub. No.: US 2010/0052814 A1
(43) Pub. Date: Mar. 4, 2010

(54) Controlled RF Active Duplexer

(75) Inventors: Jean-Philippe Plaze, Bois D'Arcy (FR); Philippe Dueme, Orsay (FR); Benoit Mallet-Guy, Paris (FR)

Correspondence Address: BAKER & HOSTETLER LLP, WASHINGTON SQUARE, SUITE 1100, 1050 CONNECTICUT AVE. N.W., WASHINGTON, DC, 20036-5304, US

(73) Assignee: Thales, Neuilly/Sur/Seine (FR)

(21) Appl. No.: 12/549,064

(22) Filed: Aug. 27, 2009

(30) Foreign Application Priority Data
Aug. 29, 2008 (FR) 08 04762

(51) Int. Cl. H03H 7/46

(52) U.S. Cl. 333/132; 330/286

(57) ABSTRACT

A controlled RF active duplexer comprises two distributed amplifiers and means for controlling them. Each distributed amplifier comprises an input line and an output line, the output line of the first distributed amplifier being common to the input line of the second distributed amplifier. An end of the input line of the first distributed amplifier forms the input port, an end of the output line of the second distributed amplifier forms the output port and an end of the line common to the two distributed amplifiers forms the input/output port. The distributed amplifiers are placed in the on state or in the off state in opposition to one another as a function of the ports to be made to communicate. The invention makes it possible to carry out the splitting of the RF signals within a compact space and isolation between input port and output port.

### CROSS-REFERENCE TO RELATED APPLICATIONS

This application claims priority of French application no. FR 0804762, filed Aug. 29, 2008, the disclosure of which is hereby incorporated by reference in its entirety.

### TECHNICAL FIELD

The invention relates to a controlled RF active duplexer. It relates also to a transmission and reception module comprising such an RF active duplexer. The invention applies notably to the field of transmission and reception modules using a single antenna for transmission and reception. It applies more particularly to the field of the transmission and reception modules of airborne systems operating in a wide frequency band.

### BACKGROUND OF THE INVENTION

Transmission and reception modules using a single antenna for transmission and reception, such as for example the transmission and reception modules with which certain radars are equipped, must comprise means making it possible to separate the signals transmitted from the signals received by the antenna. Indeed, the transmit chain and the receive chain exhibit different electrical characteristics, the use of one and the same antenna for the transmission and reception of signals makes it necessary to separate the signals transmitted from the signals received as close as possible to the antenna. For good operation of the transmission and reception module, the means making it possible to separate the signals transmitted from the signals received must satisfy various constraints. Firstly, they must ensure good isolation between the transmit pathway and the receive pathway so as to prevent disturbance or even damage to the receiver, whose sensitivity is significant, by the undesirable reception of an overly significant fraction of the signal transmitted. The isolation between the transmit pathway and the receive pathway is all the more significant as the discrepancy in power level between the signal transmitted and the signal received may reach a ratio of the order of 10 000, or even more. Secondly, in receive mode these means must ensure that the signal received travels to the receiver with a minimum of losses, the power of the signal received being generally low, or even very low. Thirdly, in transmit mode these means must ensure that the signal transmitted travels to the antenna with a minimum of losses so as not to degrade the power efficiency of the transmission and reception module. Moreover, the growing requirement for the integration of airborne systems leads to reductions in the weight and overall proportions of signal processing devices, thus favouring the development of transmission and reception modules installed as close as possible to the antenna.

For applications with a relatively narrow band of frequencies, of the order of an octave, the means making it possible to separate the signals transmitted from the signals received are generally designed in two parts:
a first part deals with the splitting of the signal at the foot of the antenna between the transmit pathway and the receive pathway;
a second part covers the switching of the processing of the signal according to the operating mode.

The splitting of the signal at the foot of the antenna is generally carried out by a non-reciprocal passive circuit of the ferrite circulator type. An RF circulator carries out its function effectively. It may be cascaded with one or more other circulators, so as notably to enhance the isolation between pathways. On the other hand, a circulator has significant overall proportions and significant weight, which are penalizing for airborne systems. Moreover, the bandwidth of a circulator proves to be insufficient for very wide band applications, typically of the order of 3 octaves and more. For very broad band applications, the splitting between the transmit pathway and the receive pathway may be carried out with the aid of a passive switch. However, the main limitation of a passive switch is the absence of directivity between the input and the output of one and the same pathway thereof. Stated otherwise, the input and the output of a pathway of the passive switch are in direct and bilateral linkage, to within transmission losses, when this pathway of the switch is triggered. The absence of directivity poses a problem notably when the antenna exhibits a high coefficient of reflection. A part of the signal to be transmitted is then reflected towards the power amplifier, possibly causing its malfunction or even its destruction. Another solution for very broad band applications consists in physically separating the transmit pathway from the receive pathway. This separation exhibits an obvious drawback, namely the duplication of a part of the signal processing chain and radiating elements, this being contrary to the philosophy of a transmission and reception module and to the requirement for the integration of electronic devices.

### SUMMARY OF THE INVENTION

An aim of the invention is notably to alleviate all or some of the aforesaid drawbacks. For this purpose, the subject of the invention is a controlled RF active duplexer comprising an input port, an input/output port and an output port and allowing the passage of an RF signal from the input port to the input/output port and from the input/output port to the output port. According to the invention, the active duplexer comprises two distributed amplifiers and means for controlling them. Each distributed amplifier comprises an input line and an output line, the output line of the first distributed amplifier being common to the input line of the second distributed amplifier. An end of the input line of the first distributed amplifier forms the input port; an end of the output line of the second distributed amplifier forms the output port and an end of the line common to the two distributed amplifiers forms the input/output port. The first distributed amplifier is placed in the on state and the second distributed amplifier is placed in the off state when an RF signal is apt to pass from the input port to the input/output port, and the first distributed amplifier is placed in the off state and the second distributed amplifier is placed in the on state when an RF signal is apt to pass from the input/output port to the output port.

The subject of the invention is also a transmission and reception module comprising an RF active duplexer as described hereinabove. The input port is linked to a transmit pathway, the input/output port is able to be linked to an antenna and the output port is linked to a receive pathway.

The advantage of the invention is notably that it makes it possible to carry out the splitting of the RF signals within a compact space and good isolation between the input port and the output port.

### BRIEF DESCRIPTION OF THE DRAWINGS

The invention will be better understood and other advantages will become apparent on reading the detailed description of an embodiment given by way of example, the description being offered in conjunction with the appended drawings which represent:

FIG. 1, an illustration of means making it possible to separate the signals transmitted from the signals received and that can be installed in a transmission and reception module according to the prior art for a narrow band application;

FIG. 2, an illustration of a distributed amplifier such as is known from the prior art;

FIG. 3, an illustration of the principle of embodiment of the controlled RF active duplexer according to the invention;

FIG. 4, curves of evolution as a function of frequency of parameters of transmission between various access ports of the distributed amplifier of FIG. 2;

FIG. 5, an exemplary embodiment of a controlled RF active duplexer according to the invention;

FIG. 6, an equivalent electrical diagram of the controlled RF active duplexer as presented in FIG. 5 in the transmit mode;

FIG. 7, an equivalent electrical diagram of the controlled RF active duplexer as presented in FIG. 5 in the receive mode.

### DETAILED DESCRIPTION OF THE PREFERRED EMBODIMENT

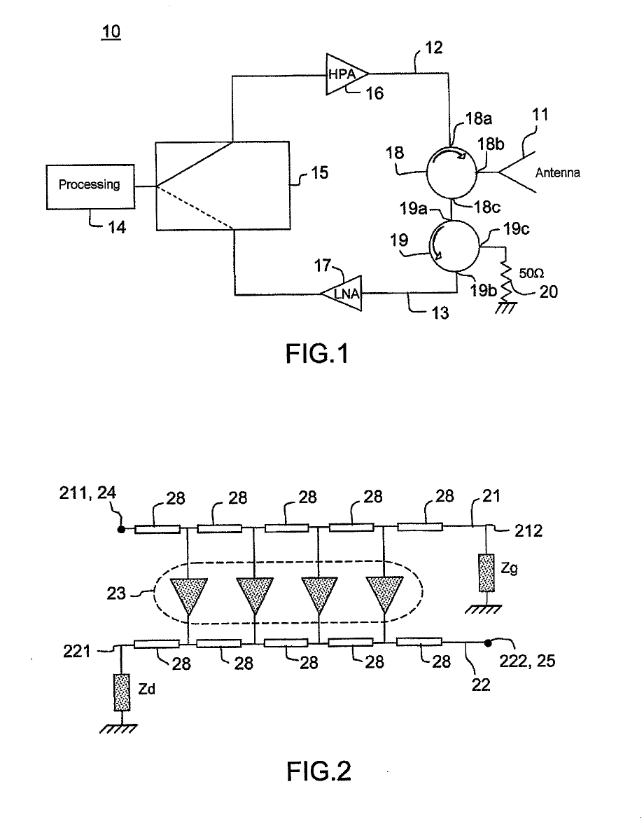

FIG. 1 illustrates, through a schematic, means 10 making it possible to separate the signals transmitted from the signals received by an antenna 11, these means 10 being able to be installed in a transmission and reception module for a narrowband application. As indicated previously, these means 10 perform on the one hand the splitting of the signals at the foot of the antenna 11 between the transmit pathway 12 and the receive pathway 13 and on the other hand the switching of the processing of the signals according to the operating mode, namely the transmit mode or the receive mode. The transmit pathway 12 and receive pathway 13 are linked to processing means 14 by a switch 15. The switch 15 ensures the linkage between the processing means 14 and one or other of the transmit pathway 12 and receive pathway 13, depending on the operating mode in progress. The transmit pathway 12 generally comprises a power amplifier 16 intended for amplifying the low power signal emanating from the processing means 14, the amplified signal being intended to be transmitted by the antenna 11. The receive pathway 13 generally comprises a low noise amplifier 17 for amplifying the low power signal received by the antenna 11 and heading for the processing means 14. In the example of FIG. 1, the splitting is performed by means of two RF circulators 18 and 19. The first circulator 18 receives on an input 18a the amplified signals emanating from the power amplifier 16. An input/output 18b of the circulator 18 is linked to the antenna 11, so that the amplified signal is directed towards the latter. The switching function is located upstream of the power amplifier 16. The signals which pass through the switch 15 may then be of low power. On reception, the signals emanating from the antenna 11 enter the input/output 18b of the first circulator 18 so as to be directed towards an output 18c linked to an input 19a of the second circulator 19. The signal received is directed inside the circulator 19 towards an input/output 19b linked to the receive pathway 13 and notably to the input of the low noise amplifier 17. The output 19c of the second circulator 19 is linked to a 50 ohm load 20. The second circulator 19 enhances the isolation between the transmit pathway 12 and the receive pathway 13. The number of circulators used depends on the level of isolation desired between the transmit pathway 12 and the receive pathway 13. In the case of minimal isolation, the output 18c of the first circulator 18 is linked directly to the input of the low noise amplifier 17.

The use of circulators makes it possible to dissociate the transmit path 12 and receive path 13 at the level of the antenna 11. The circulators being passive elements, they are naturally able to pass high power signals coming from the power amplifier 16. However, on account of their weight, their volume and their limited bandwidth, circulators are unsuited to the wideband applications of airborne systems.

The present invention relies on the combining of two distributed amplifiers.

FIG. 2 illustrates, through a schematic, the structure of a distributed amplifier. Such a device essentially comprises an input line 21 and an output line 22 which are linked by active cells 23. The input line 21 and output line 22 are generally closed up at one of their ends, respectively 212 and 221, by a load impedance, respectively Zg and Zd, whose value is in principle equal to the characteristic impedance of the line in question. The free ends 211 and 222 of the input line 21 and output line 22 form respectively an input port 24 and an output port 25 for the distributed amplifier. The input port 24 and the output port 25 are situated opposite one another. The active cells 23 may notably each comprise a transistor, for example a field-effect transistor in common-source mode whose gate is linked to the input line 21 and whose drain is linked to the output line 22. In this case the input line 21 is commonly called the gate line and the output line, the drain line. The active cells 23 may also comprise an arrangement associating several transistors, for example an arrangement of Darlington, cascade or cascode type.

The input line 21 and output line 22 each consist of a combination between inductors and the access ports of the transistors, which have capacitive properties. For example, in the case of a field-effect transistor, the gate access port (at input) and drain access port (at output) are equivalent to capacitors of capacitance Cgs at input and of capacitance Cds at output. The inductors may be physically embodied by sections of RF lines 28 of high characteristic impedance, such as microstrip lines of small width. They may also be embodied by spiral-shaped components. To increase the bandwidth, it is also possible to introduce a mutual inductance effect between two consecutive inductors by using nested spirals. In FIG. 2, the input line 21 and output line 22 are represented symbolically by sections of lines 28 linking the various active cells 23.

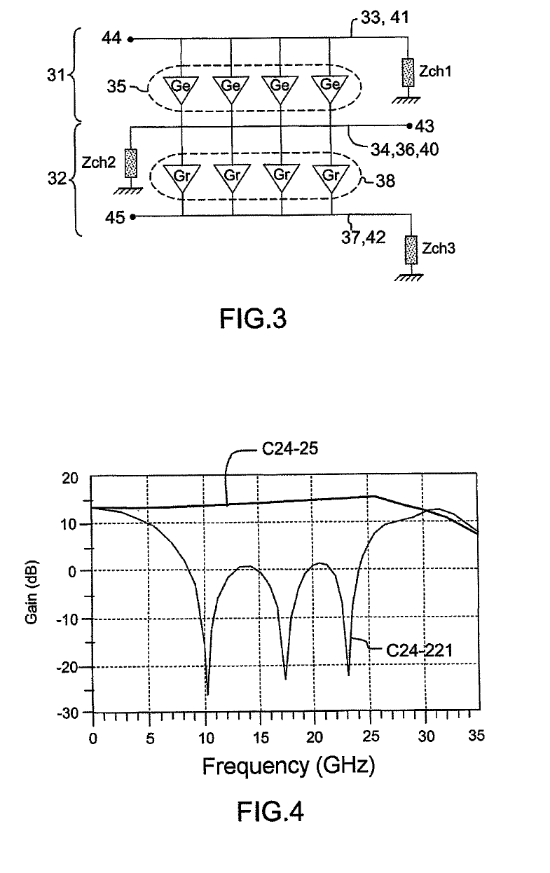

FIG. 3 illustrates the principle of embodying a controlled RF duplexer according to the invention. Said controlled RF active duplexer comprises two distributed amplifiers 31 and 32 such as are described with reference to FIG. 2. In particular, the first distributed amplifier 31 comprises a first input line 33 and a first output line 34, these lines being linked by active cells 35. The second distributed amplifier 32 comprises a second input line 36 and a second output line 37. Likewise, the second input line 36 and output line 37 are linked by active cells 38. According to the invention, the first output line 34 is common to the second input line 36. Stated otherwise, the first output line 34 and the second output line 36 are physically embodied by one and the same physical line, called the central line 40. The first input line 33, called the input line 41, the central line 40 and the second output line 37, called the output line 42, are each closed up on a load impedance, respectively Zch1, Zch2 and Zch3, equal to the characteristic impedance of the respective line 40, 41 or 42. The free ends of the central 40, input 41 and output 42 lines respectively form an input/output port 43, an input port 44 and an output port 45.

FIG. 3 presents a particular case where the distributed amplifiers 31 and 32 each comprise the same number of active cells 35 and 38. However, the number of active cells 35 is entirely independent of the number of active cells 38.

According to a particular embodiment, the input/output port 43 is situated opposite the input port 44 and opposite the output port 45, as represented in FIG. 3. This embodiment, which is particularly advantageous, is in accordance with the customary layout of a distributed amplifier for which the output port is situated on the opposite side to the input port. Within the context of the invention, this layout makes it possible to obtain good isolation between the input port 44 and the output port 45. Indeed, the input port 44 and the output port 45 become naturally isolated from one another by the characteristics of a distributed amplifier, and become so independently of the off or on state of the active cells 35 and 38.

FIG. 4 elucidates the isolation afforded by the layout of a distributed amplifier as represented in FIG. 2. This figure presents curves of evolution versus frequency of various transmission parameters relating to a distributed amplifier such as represented in FIG. 2 and for which the ends 212 and 221 are not closed up on the respective closure impedances Zg and Zd but form input/output ports. A first curve C24-25 represents the coefficient of transmission, expressed in dB, between the input port 24 and the output port 25. A second curve C24-221 represents the coefficient of transmission, again expressed in dB, between the input port 24 and the end 221 of the output line 22. The first curve C24-25 makes it possible to verify that a signal injected on the input port 24 emerges amplified on the output port 25. The amplification is relatively uniform over the bandwidth of the distributed amplifier. This characteristic is due to the fact that an incoming signal entering the input port 24 is propagated over the input line 21 and is actively coupled to the output line 22. The expression active coupling is understood to mean the fact that a signal propagated over the input line 21 is decomposed into elementary signals, these elementary signals being amplified by passing each through an active cell 23, the amplified elementary signals being recombined in phase at the level of the output port 25. Conversely, the signal portion received on the end 221 of the output line 22, represented by the curve C24-221, is broadly attenuated on certain frequency bands. The attenuation is due to the fact that the elementary signals are phase shifted with respect to one another at the level of the end 221 of the output line 22.

The principle of natural isolation of a distributed amplifier is obviously found again in the RF active duplexer according to the invention, for example represented in FIG. 3. Indeed, on account of the combining of two distributed amplifiers, an incoming signal entering on the input port 44 is amplified at output on the input/output port 43, just as an incoming signal entering on the input/output port 43 is amplified at output on the output port 45, whereas an incoming signal entering on the input port 44 is strongly attenuated at output on the output port 45.

The principle of natural isolation and of uniform amplification is all the more effective as the active cells 35 on the one hand, and 38 on the other hand, are spread out uniformly between the respective input lines 33, 36 and output lines 34, 37. The expression uniformly spread out is understood to mean the fact that the equivalent electric lengths of the various paths traversed by the elementary signals between the input port 44 and the input/output port 43 or between the input/output 43 and the output port 45 are equal, so that the RF signal is recombined in phase respectively on the output line 34 or 37 of the first or of the second distributed amplifier 31 or 32 depending on whether the RF signal enters respectively on the input line 33 or the input line 36.

According to a particular embodiment, the RF active duplexer comprises a control circuit making it possible to control the active cells 35 and 38 as a function of the mode, transmit or receive. In particular, in the transmit mode, stated otherwise when an RF signal is apt to pass from the input port 44 to the input/output port 43, the control circuit places the active cells 35 of the first distributed amplifier 31 in the on state and the active cells 38 of the second distributed amplifier 32 in the off state. Conversely, in the receive mode, stated otherwise when an RF signal is apt to pass from the input/output port 43 to the output port 45, the control circuit places the active cells 35 of the first distributed amplifier 31 in the off state and the active cells 38 of the second distributed amplifier 32 in the on state. This embodiment makes it possible to enhance the isolation between the input port 44 and output port 45.

Advantageously, the active cells 35 and 38 each comprise a transistor. These transistors are for example field-effect transistors arranged in common-source mode. The gates of the transistors of the active cells 35 may be linked to the input line 41 and their drains may be linked to the central line 40. Likewise, the gates of the transistors of the active cells 38 may be linked to the central line 40 and their drains may be linked to the output line 42. The use of transistors makes it possible to amplify the signals passing through the active cells 35 and 38. The amplification gain Ge of the active cells 35 may be different from the amplification gain Gr of the active cells 38. Advantageously, the transistors are dimensioned in such a way that the first distributed amplifier 31 of the controlled RF active duplexer can be substituted for the power amplifier 16 of the switching device 10 represented in FIG. 1 and that the second distributed amplifier 32 can be substituted for the low noise amplifier 17 of this switching device 10.

In a particular embodiment, the active cells 35 and 38 each comprise an arrangement associating several transistors, for example a Darlington arrangement or a cascode arrangement. The use of several transistors per active cell 35 or 38 has the advantage notably of being able to easily adjust the gains Ge and Gr of the active cells 35 and 38.

Again advantageously, the transistors of the active cells 35 and 38 are fabricated using a technology involving wide-gap type III-V semiconductors, such as for example Gallium Nitride (GaN). This technology makes it possible to produce components having high breakdown voltages and significant power densities. These characteristics present several advantages. In receive mode, the controlled RF active duplexer exhibits a relatively high robustness to outside attacks such as strong fields. The presence of a protective device is then no longer necessary. This results in an improvement in the noise factor and hence in the sensitivity of the reception chain. In transmit mode, it is possible to produce the power amplification solely with the active cells 35 of the first distributed amplifier 31.

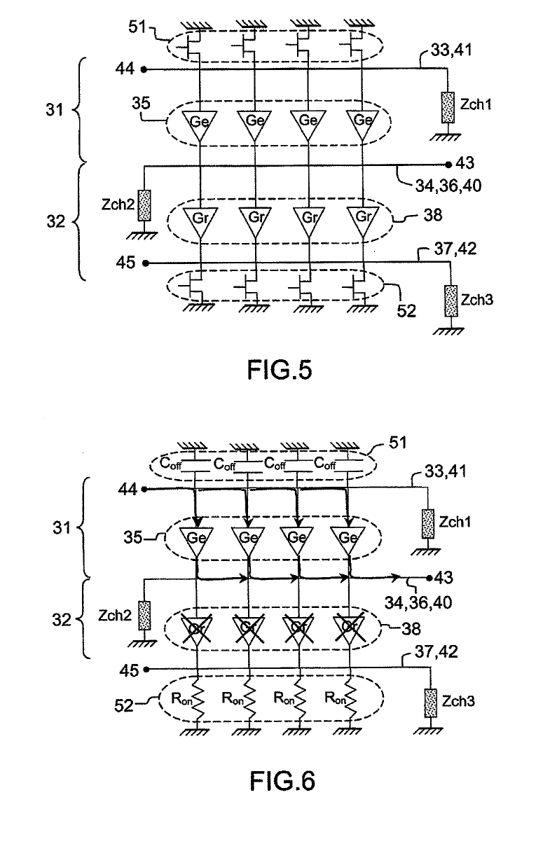

FIG. 5 illustrates a controlled RF active duplexer according to a particular embodiment of the invention. According to this particular embodiment, the RF active duplexer comprises, furthermore, switching elements 51 spread out along the input line 41 and making it possible to link this line to a ground plane. The switching elements 51 comprise for example so-called “cold” transistors, that is to say field-effect transistors whose DC voltage between the drain and the source is always zero. Likewise, the RF active duplexer can comprise switching elements 52 spread out along the output line 42 and making it possible to link this line to a ground plane. The switching elements 52 comprise for example cold transistors.

The characteristics of a cold transistor are as follows. When the cold transistor is on, for example for a DC voltage Vgs equal to 0.5 V applied between its gate and its source, the transistor exhibits the characteristics of a low resistance Rₒₙ between its drain and its source. When the cold transistor is off, for example for a DC voltage Vgs equal to −2.2 V, the transistor exhibits the characteristics of a capacitance C_{off}.

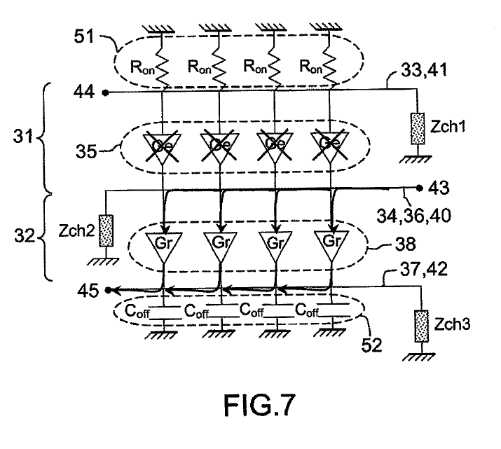

Advantageously, the RF active duplexer comprises a control circuit making it possible to control the switching elements 51 and 52 as a function of the transmit or receive mode. In particular, in the transmit mode, represented in FIG. 6, the control circuit places the switching elements 51 in the off state and the switching elements 52 in the on state. Consequently, the input line 41 preserves the characteristics of a propagation line whereas the output line 42 possesses regular connections to ground, absorbing any leakage signal arriving on the output line 42 and thus reducing the propagation of this leakage signal towards the output port 45. Conversely, in the receive mode, represented in FIG. 7, the control circuit places the switching elements 51 in the on state and the switching elements 52 in the off state. The input line 41 then possesses regular connections to ground, capable of absorbing any leakage signal, whereas the output line 42 preserves the characteristics of a propagation line.

It should be noted that, so as not to reduce the bandwidths of the first and second distributed amplifiers 31 and 32, the capacitances C_{off} must remain small. Stated otherwise the cold transistors must be of small size.

The particular embodiment given with reference to FIGS. 5 to 7 describes an RF active duplexer comprising switching elements 51 spread out over the input line 41 and also switching elements 52 spread out over the output line 42. However, the RF active duplexer may equally well comprise switching elements 51 and 52 solely on one of the two lines, input 41 and output 42. Likewise, FIG. 5 presents a particular case where a switching element 51, respectively 52, is present for each active cell 35, respectively 38. The number of switching elements 51 and 52 may however be entirely independent of the number of active cells 35 and 38.

The RF active duplexer as described hereinabove may be installed in a transmit and receive module, for example a transmit and receive module of an airborne system. The input port 44 may be linked to a transmit pathway, for example an output of a power amplifier, the input/output port 43 may be linked to an antenna and the output port 45 may be linked to a receive pathway, for example an input of a low noise amplifier. By suitably controlling the operation of the active cells 35 and 38, the controlled RF active duplexer can then ensure a function equivalent to the circulators 18 and 19, allowing the passage of an RF signal from the input port 44 to the input/output port 43 and from the input/output port 43 to the output port 45.

1. A controlled RF active duplexer comprising an input port, an input/output port and an output port and allowing the passage of an RF signal from the input port to the input/output port and from the input/output port to the output port, the duplexer further comprising two distributed amplifiers and means for controlling said distributed amplifiers, each distributed amplifier comprising an input line and an output line, the output line of the first distributed amplifier being common to the input line of the second distributed amplifier, an end of the input line of the first distributed amplifier forming the input port, an end of the output line of the second distributed amplifier forming the output port and an end of the line common to the two distributed amplifiers forming the input/output port, the first distributed amplifier being placed in the on state and the second distributed amplifier being placed in the off state when an RF signal is apt to pass from the input port to the input/output, the first distributed amplifier being placed in the off state and the second distributed amplifier being placed in the on state when an RF signal is apt to pass from the input/output port to the output port.

2. The duplexer of claim 1, wherein each distributed amplifier comprises transistors in parallel between its input line and its output line, the transistors being spread out uniformly so that whichever transistor is traversed by the RF signal between the input port and the input/output port or between the input/output port and the output port, the RF signal is recombined in phase respectively on the output line of the first or of the second distributed amplifier.

3. The duplexer of claim 2, wherein the transistors comprise wide-gap III-V type semiconductor materials.

4. The duplexer of claim 1, further comprising switching elements spread out along the input line of the first distributed amplifier making it possible to link said input line to a ground plane.

5. The duplexer of claim 1, further comprising switching elements spread out along the output line of the second distributed amplifier making it possible to link said output line to a ground plane.

6. The duplexer of claim 5, further comprising switching elements spread out along the input line of the first distributed amplifier making it possible to link said input line to a ground plane, and further comprising means for turning off the switching elements spread out along the input line of the first distributed amplifier and for turning on the switching elements spread out along the output line of the second distributed amplifier when an RF signal has to pass from the input port to the input/output port and means for turning on the switching elements spread out along the input line of the first distributed amplifier and for turning off the switching elements spread out along the output line of the second distributed amplifier when an RF signal has to pass from the input/output port to the output port.

7. The duplexer of claim 5, further comprising switching elements spread out along the input line of the first distributed amplifier making it possible to link said input line to a ground plane, and wherein the switching elements spread out along the input line of the first distributed amplifier and the switching elements spread out along the output line of the second distributed amplifier are field-effect transistors whose DC voltage between their drain and their source is always zero.

8. A transmission and reception module comprising the controlled RF active duplexer of claim 1, the input port being linked to a transmit pathway, the input/output port being able to be linked to an antenna and the output port being linked to a receive pathway.

9. The module according to claim 8, wherein the transmit pathway comprises a power amplifier linked upstream to a point able to be connected to processing means and the receive pathway comprises a low noise amplifier linked downstream to a point able to be connected to processing means.
